(19) United States
(12) Patent Application Publication
(10) Pub. No.: US 2018/0174989 A1
(43) Pub. Date: Jun. 21, 2018

(54) METHOD FOR PRODUCING SOLDERED ELECTRODE AND USE THEREOF

(71) Applicant: JSR CORPORATION, TOKYO (JP)

(72) Inventors: JUN MUKAWA, MINATO-KU, TOKYO (JP); SEIICHIROU TAKAHASHI, MINATO-KU, TOKYO (JP); KOUICHI HASEGAWA, MINATO-KU, TOKYO (JP); SHIROU KUSUMOTO, MINATO-KU, TOKYO (JP)

(73) Assignee: JSR CORPORATION, TOKYO (JP)

(21) Appl. No.: 15/565,904

(22) PCT Filed: Mar. 1, 2016
(86) PCT No.: PCT/JP2016/056214

§ 371 Date: Feb. 14, 2018

(30) Foreign Application Priority Data
Apr. 16, 2015 (JP) 2015-083990
Dec. 2, 2015 (JP) 2015-235564

(51) Int. Cl. H01L 23/00

(52) U.S. Cl. CPC H01L 24/11; H01L 24/81; H01L 2224/11618; H01L 2224/1131; H01L 2224/1147

(57) ABSTRACT

The present disclosure relates to a production process for a solder electrode, including a step (1) of forming a coating film of a photosensitive resin composition on a substrate having an electrode pad; a step (2) of forming resist having an opening in a region corresponding to the electrode pad by selectively exposing the coating film to light and further developing the film; a step (3) of heating and/or exposing the resist to light; and a step (4) of filling the opening with molten solder while heating the solder. According to the production process for the solder electrode of the present disclosure, development of cracks on a resist surface can be prevented, and solder filling capability can be improved, even when the resist receives high heat during solder filling as in an IMS method, and therefore the solder electrode adapted for the purpose can be appropriately produced.

### TECHNICAL FIELD

The present invention relates to a production process for a solder electrode, a solder electrode, a production process for a laminate, a laminate and an electronic component.

### BACKGROUND ART

An IMS (injection molded solder) method is one of methods for forming a solder pattern such as a solder bump. As the methods for forming the solder pattern on a substrate such as a wafer, a solder paste method, a plating method and the like have been used so far. In these methods, however, control of a height of the solder bump is difficult, and in addition thereto, there have been restrictions of incapability of freely selecting a solder composition, or the like. In contrast, the IMS method is known to have an advantage of being free from these restrictions.

As shown in Patent literature 1 to 4, the IMS method is a method being characterized in that molten solder is injected into an opening of a resist pattern to fill the opening with the solder, while a nozzle from which the molten solder can be injection-molded is brought into close contact with resist.

### CITATION LIST

### Patent Literature

Patent literature 1: Japanese Patent Laid-Open Publication No. 1994-055260
Patent literature 2: Japanese Patent Laid-Open Publication No. 2007-294954
Patent literature 3: Japanese Patent Laid-Open Publication No. 2007-294959
Patent literature 4: Japanese Unexamined Patent Application Publication (Translation of PCT Application) No. 2013-520011

### SUMMARY OF INVENTION

An IMS method is performed by pressing an IMS head heated to a high temperature, ordinarily to 250° C. or more, onto a resist surface in order to fill openings with molten solder. Therefore, there has been a problem of reduction of solder filling capability because a load caused by high heat is applied onto the resist surface to develop cracks on the resist surface or blisters of resist.

An object of the present invention is to provide a technology according to which the solder filling capability can be improved by preventing development of the cracks on the resist surface, even when the resist receives high heat during solder filling as in the IMS method.

### Solution to Problem

A production process for a solder electrode according to the present invention includes: a step (1) of forming a coating film of a photosensitive resin composition on a substrate having an electrode pad; a step (2) of forming resist having an opening in a region corresponding to the electrode pad by selectively exposing the coating film to light and further developing the film; a step (3) of heating and/or exposing the resist to light; and a step (4) of filling the opening with molten solder while heating the molten solder.

In the production process for the solder electrode, the step (3) is preferably a step of heating the resist, and a heating temperature in the step (3) is preferably 100 to 300° C.

The production process for the solder electrode can further include a step (5) of peeling the resist from the substrate.

A solder electrode of the present invention is produced by the production process for the solder electrode.

A first production process for a laminate according to the present invention includes: a step (1) of forming a coating film of a photosensitive resin composition on a first substrate having an electrode pad; a step (2) of forming resist having an opening in a region corresponding to the electrode pad by selectively exposing the coating film to light and further developing the film; a step (3) of heating and/or exposing the resist to light; a step (4) of producing a solder electrode by filling the opening with molten solder while heating the molten solder; and a step (6) of forming an electrical connection structure between the electrode pad of the first substrate and an electrode pad of a second substrate having the electrode pad through the solder electrode.

A second production process for a laminate according to the present invention includes: a step (1) of forming a coating film of a photosensitive resin composition on a first substrate having an electrode pad; a step (2) of forming resist having an opening in a region corresponding to the electrode pad by selectively exposing the coating film to light and further developing the film; a step (3) of heating and/or exposing the resist to light; a step (4) of filling the opening with molten solder while heating the molten solder; a step (5) of peeling the resist from the first substrate; and a step (6) of forming an electrical connection structure between the electrode pad of the first substrate and an electrode pad of a second substrate having the electrode pad through the solder electrode.

A laminate of the present invention is produced by the production process for the laminate.

An electronic component of the present invention has the laminate.

### Advantageous Effects of Invention

According to a production process for a solder electrode of the present invention, development of cracks on a resist surface can be prevented, and solder filling capability can be improved, even when resist receives high heat during solder filling as in an IMS method, and therefore the solder electrode adapted for the purpose can be appropriately produced.

According to a production process for a laminate of the present invention, a solder electrode adapted for the purpose can be appropriately produced by an IMS method, and therefore the laminate having an electrical connection structure can be appropriately produced.

### BRIEF DESCRIPTION OF DRAWINGS

FIGS. 1(1) to 1(5) are each a schematic sectional view of a structure containing a substrate in each step in a production process for a solder electrode according to the present invention.

FIGS. 2(6-1) and 2(6-2) are each a schematic sectional view of a laminate according to the present invention.

FIG. 3 is an electron microscopic image showing a state of resist and a solder electrode provided on a substrate in Example 1.

FIG. 4 is an electron microscopic image showing a state of a solder electrode provided on a substrate in Example 1.

### DESCRIPTION OF EMBODIMENTS

<Production Process for a Solder Electrode>

A production process for a solder electrode according to the present invention includes: a step (1) of forming a coating film of a photosensitive resin composition on a substrate having an electrode pad; a step (2) of forming resist having an opening in a region corresponding to the electrode pad by selectively exposing the coating film to light and further developing the film; a step (3) of heating and/or exposing the resist to light; and a step (4) of filling the opening with molten solder while heating the molten solder.

In a conventional production process for the solder electrode by an IMS method or the like, the resist having the opening is formed on the substrate having the electrode pad, and then the opening is filled with the molten solder without heating or exposing the resist to light. However, the production process for the solder electrode according to the present invention is characterized by performing the step (3) of heating and/or exposing the resist to light before filling the opening with the molten solder after forming the resist having the opening on the substrate having the electrode pad. Any operation other than this point may be similar to the operation in the conventional production process for the solder electrode by the IMS method.

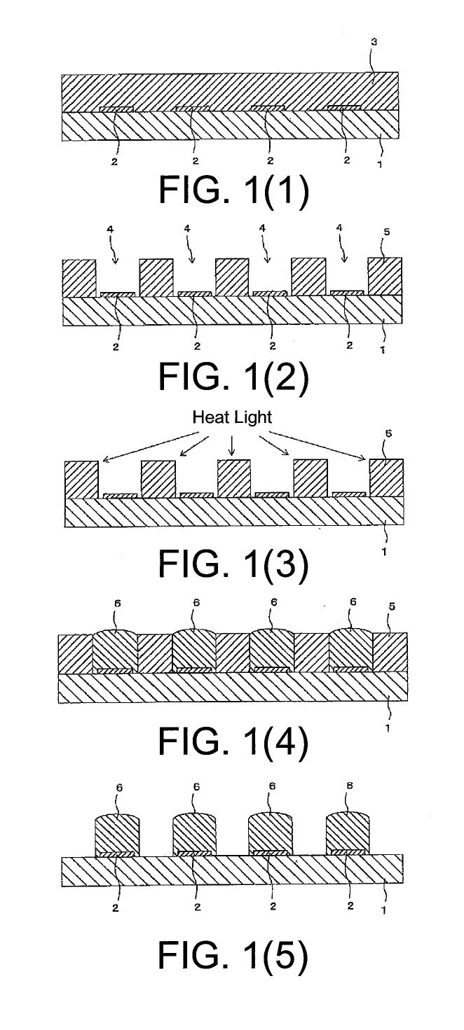

Hereinafter, the production process for the solder electrode according to the present invention will be described with reference to FIG. 1.

### (Step 1)

In the step 1, as shown in FIG. 1(1), a coating film 3 of a photosensitive resin composition is formed on a substrate 1 having an electrode pad 2.

Specific examples of the substrate 1 include a semiconductor substrate, a glass substrate and a silicon substrate, and a substrate formed by providing various metal films on a surface of a semiconductor board, a glass board and a silicon board. The substrate 1 has a large number of electrode pads 2.

The coating film 3 is formed by coating a photosensitive resin composition onto the substrate 1, or the like. The photosensitive resin composition may be a photosensitive resin composition which has been used so far for resist formation in the IMS method. The photosensitive resin composition ordinarily contains a crosslinking agent, such as polyfunctional acrylate, and the coating film 3 formed of the photosensitive resin composition is crosslinked in the step 2 described later. A method for coating the photosensitive resin composition thereonto is not particularly limited, and specific examples thereof can include a spraying method, a roll coating method, a spin coating method, a slit die coating method, a bar coating method and an inkjet method. A film thickness of the coating film 3 is ordinarily 0.001 to 10 μm, preferably 0.01 to 5 μm, and further preferably 0.1 to 1 μm.

### (Step 2)

In the step (2), as shown in FIG. 1(2), a resist 5 having an opening 4 is formed in a region corresponding to each electrode pad 2 by selectively exposing the coating film 3 to light and further developing the film.

More specifically, the opening 4 housing each electrode pad 2 is formed by partially exposing the coating film 3 to light and then developing the film so that the opening 4 housing each electrode pad 2 may be formed thereon. As a result, the resist 5 having the opening 4 in the region corresponding to each electrode pad 2 is obtained. The opening 4 is a hole penetrating through the resist 5. Exposure and development can be performed according to a conventional method. A maximum width of the opening 4 is ordinarily 0.1 to 10 times the film thickness of the coating film 3, and preferably one half to twice the film thickness thereof.

### (Step 3)

In the step 3, as shown in FIG. 1(3), the resist 5 is heated and/or exposed to light. More specifically, the resist 5 is heated but not exposed to light, exposed to light but not heated, or heated and exposed to light. Even when the opening 4 is filled with the molten solder by pressing a hot head onto the surface of the resist 5 as in the IMS method, development of cracks on the surface of the resist 5 and blisters of resist can be suppressed by performing this step, solder filling capability can be improved, and as a result, the solder electrode adapted for the purpose can be appropriately produced. The reason therefor can be considered as described below.

As described above, in the step 2, the coating film 3 formed of the photosensitive resin composition is crosslinked by exposure to light. However, the crosslinking agent contained in the photosensitive resin composition is ordinarily not completely consumed only by the exposure to light, and an unconsumed crosslinking agent remains in the resist 5. On this account, at a time point at which the step 2 is completed, crosslinking of the resist 5 is incomplete and strength of the resist 5 is not sufficiently enhanced. When the opening 4 is filled with the molten solder by pressing the hot head onto the surface of the resist 5 in this state by the IMS method, as in the conventional method, the resist 5 fails to withstand the heat received from an IMS head, and the cracks and the blisters are conceivably developed.

In the production process for the solder electrode according to the present invention, on the other hand, the resist 5 is heated and/or exposed to light as the step 3 after completion of the step 2. A crosslinking reaction by the crosslinking agent remaining in the resist 5 progresses by this operation, and the resist 5 is strengthened. Then, when the opening 4 is filled with the molten solder by pressing the hot head onto the surface of the resist 5 as in the IMS method, the resist 5 has strength enough to withstand the heat received from the IMS head, and therefore neither the cracks nor the blisters are conceivably developed.

In addition, also in the conventional IMS method in which the resist 5 is not heated and/or exposed to light after completion of the step 2, the crosslinking reaction by the crosslinking agent progresses within the resist 5 by heat during filling the opening 4 with the molten solder and the resist 5 is conceivably strengthened. However, a crosslinking reaction rate is low in the crosslinking agent such as the polyfunctional acrylate used in the photosensitive resin composition, and therefore the cracks and the blisters are conceivably developed by the heat received from the IMS head before the crosslinking reaction sufficiently progresses.

When the resist 5 is heated in the step 3, a heating temperature is ordinarily 100 to 300° C., and preferably 150 to 250° C. A heating time is ordinarily 5 to 120 minutes, and preferably 5 to 60 minutes. The time is adjusted according to a quantity of heat, for example, the heating time is shortened when the heating temperature is high, and the heating time is lengthened when the heating temperature is low.

When the resist 5 is exposed to light in the step 3, an amount of exposure to light is ordinarily 50 to 3,000 mJ/cm², and preferably 100 to 1,000 mJ/cm². A time of exposure to light is ordinarily 1 second to 30 minutes.

When the resist 5 is heated and exposed to light in the step 3, a heating temperature is ordinarily 100 to 300° C., and preferably 150 to 250° C., and a heating time is ordinarily 5 to 120 minutes, and preferably 5 to 60 minutes. An amount of exposure to light is ordinarily 50 to 3,000 mJ/cm², and preferably 100 to 2,000 mJ/cm², and a time of exposure to light is ordinarily 1 second to 30 minutes.

The crosslinking reaction by the crosslinking agent sufficiently progresses within the resist 5 by heating and/or exposing the resist 5 to light as described above, and the resist 5 has the strength enough to withstand the heat received during filling the opening with the molten solder.

In the step 3, the resist 5 is preferably heated because the crosslinking reaction of the crosslinking agent is easily progressed within the resist 5 to strengthen the resist 5.

### (Step 4)

In the step 4, the opening 4 is filled with the molten solder while heating the molten solder. Then, the resulting material is cooled, and as shown in FIG. 1(4), a solder electrode 6 is formed in each opening 4.

A method for filling the opening 4 with the molten solder while heating the molten solder is not particularly limited, and an ordinary filling method by the IMS method can be adopted. In the IMS method, the opening 4 is filled therewith while heating the molten solder ordinarily to 250° C. or more. According to the production process for the solder electrode of the present invention, as described above, even when the opening 4 is filled with the molten solder by pressing the hot head onto the surface of the resist 5 as in the IMS method, development of the cracks on the surface of the resist 5 and development of the blisters can be suppressed.

The solder electrode produced according to the production process for the solder electrode of the present invention as described above is formed without developing the cracks and the blisters on the resist, and therefore an electrode adapted for the purpose without any disorder of a shape or the like is formed.

The production process for the solder electrode can further include a step (5) of peeling the resist 5 from the substrate 1 after the step (4). FIG. 1(5) shows a state in which the resist 5 is peeled from the substrate 1 after the step (4).

The solder electrode produced according to the production method for the solder electrode of the present invention can be used together with the resist 5 as shown in FIG. 1(4), or can also be used without the resist 5 as shown in FIG. 1(5).

Any photosensitive resin composition can be used as long as the photosensitive resin composition contains a crosslinkable component. A case where a negative type photosensitive resin composition is used is described above, but the production process for the solder electrode of the present invention can also be performed by using a positive type photosensitive resin composition.

### <Production Process for a Laminate>

A first production process for a laminate according to the present invention includes: a step (1) of forming a coating film of a photosensitive resin composition on a first substrate having an electrode pad; a step (2) of forming resist having an opening in a region corresponding to the electrode pad by selectively exposing the coating film to light and further developing the film; a step (3) of heating and/or exposing the resist to light; a step (4) of producing a solder electrode by filling the opening with molten solder while heating the molten solder; and a step (6) of forming an electrical connection structure between the electrode pad of the first substrate and an electrode pad of a second substrate having the electrode pad through the solder electrode.

A second production process for a laminate according to the present invention includes: a step (1) of forming a coating film of a photosensitive resin composition on a first substrate having an electrode pad; a step (2) of forming resist having an opening in a region corresponding to the electrode pad by selectively exposing the coating film to light and further developing the film; a step (3) of heating and/or exposing the resist to light; a step (4) of filling the opening with molten solder while heating the molten solder; a step (5) of peeling the resist from the first substrate; and a step (6) of forming an electrical connection structure between the electrode pad of the first substrate and an electrode pad of a second substrate having the electrode pad through the solder electrode.

The steps (1) to (4) in the first production process for the laminate and the second production process therefor and the step (5) in the second production process for the laminate are substantially the same as the steps (1) to (5) in the production process for the solder electrode, respectively. More specifically, the first production process for the laminate is the process in which the step (6) is performed after the steps (1) to (4) in the production process for the solder electrode, and the second production process for the laminate is the process in which the step (6) is performed after the steps (1) to (5) in the production process for the solder electrode.

In the first and second production processes for the laminate, the substrate in the production process for the solder electrode corresponds to the first substrate.

In the first production process for the laminate, after the steps (1) to (4), the step (6) of forming the electrical connection structure between the electrode pad of the first substrate and the electrode pad of the second substrate having the electrode pad through the solder electrode is performed.

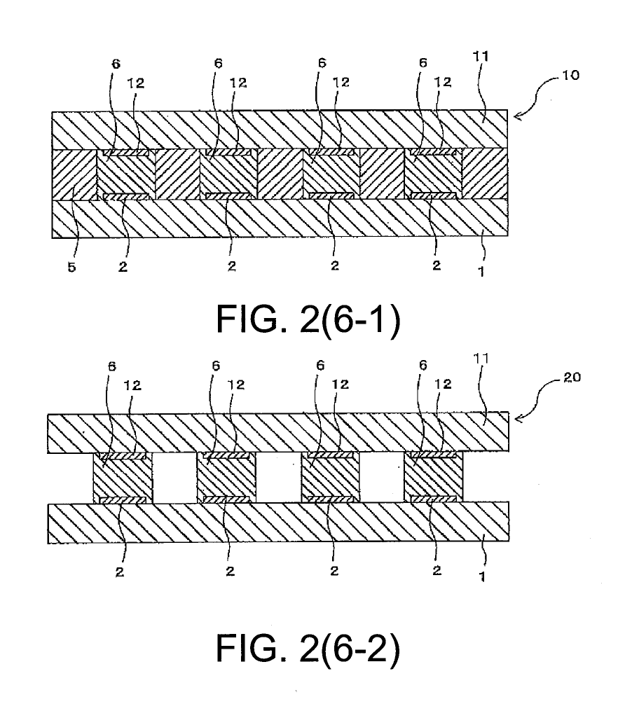

FIG. 2(6-1) shows a laminate 10 produced by the first production process for the laminate. The laminate 10 has an electrical connection structure formed by connecting the electrode pad 2 of the first substrate 1 and an electrode pad 12 of a second substrate 11 having the electrode pad 12 through the solder electrode 6 in a state shown in FIG. 1(4), which is produced by the steps (1) to (4).

The electrode pad 12 of the second substrate 11 is provided in a position facing the electrode pad 2 of the first substrate, when the first substrate 1 and the second substrate 11 are placed by facing surfaces on which the electrode pads are formed. The laminate 10 is obtained by forming the electrical connection structure by bringing the electrode pad 12 of the second substrate 11 into contact with the solder electrode 6 in the state shown in FIG. 1(4), and electrically connecting the electrode pad 2 of the first substrate 1 and the electrode pad 12 of the second substrate 11 through the solder electrode 6 by heating and/or pressuring the resulting material. The heating temperature is ordinarily 100 to 300° C., and force during the pressurization is ordinarily 0.1 to 10 MPa.

In the state shown in FIG. 1(4), the resist 5 is placed on the first substrate 1, and therefore as shown in FIG. 2(6-1), the laminate 10 has the first substrate 1, the solder electrode 6, the second substrate 11, and the resist 5 interposed between the first substrate 1 and the second substrate 11.

In the second production process for the laminate, after the steps (1) to (5), the step (6) of forming the electrical connection structure between the electrode pad of the first substrate and the electrode pad of the second substrate having the electrode pad through the solder electrode is performed.

FIG. 2(6-2) shows a laminate 20 produced by the second production process for the laminate. The laminate 20 has an electrical connection structure formed by connecting the electrode pad 2 of the first substrate 1 and the electrode pad 12 of the second substrate 11 having the electrode pad 12 through the solder electrode 6 in a state shown in FIG. 1(5), which is produced by the steps (1) to (5).

The laminate 20 is obtained by forming the electrical connection structure by electrically connecting the electrode pad 2 of the first substrate 1 by bringing the electrode pad 12 of the second substrate 11 into contact with the solder electrode 6 in the state shown in FIG. 1(5) and the electrode pad 12 of the second substrate 11 through the solder electrode 6 by heating and/or pressurizing the resulting material.

In the state shown in FIG. 1(5), the resist 5 is not placed on the first substrate 1, and therefore as shown in FIG. 2(6-2), the laminate 20 is formed of the first substrate 1, the solder electrode 6 and the second substrate 11.

As described above, the laminate produced by the production process for the laminate according to the present invention may have or need not have the resist between the first substrate and the second substrate. When the laminate has the resist as in the laminate 10, the resist is used as an underfill.

The laminate produced by the production process for the laminate according to the present invention has the electrical connection structure adapted for the purpose by the IMS method, and thus selectivity of a solder composition is extended, and therefore the laminate can be applied to various electronic components, such as a semiconductor device, a display device and a power device.

The laminate produced by the production process for the laminate according to the present invention can be used in various electronic components, such as the semiconductor device, the display device and the power device.

### EXAMPLES

Hereinafter, the present invention is further specifically described with reference to the following Examples, but the present invention is in no way limited to those Examples. In the description of the following Examples, or the like, a term “part(s)” is used in the meaning of “part(s) by mass”.

### 1. Methods for Measuring Physical Properties Method for Measuring Weight-Average Molecular Weight (Mw) of Alkali-Soluble Resin (A)

A weight-average molecular weight (Mw) was measured by gel permeation chromatography under the following conditions.
Column: TSK-M and TSK2500 being columns manufactured by Tosoh Corporation were connected in series
Solvent: tetrahydrofuran
Temperature: 40° C.
Detection method: refractive index method
Standard substance: polystyrene
GPC system: manufactured by Tosoh Corporation, system name “HLC-8220-GPC”

### 2. Preparation of Resist-Forming Composition

### [Synthesis Example 1] Synthesis of Alkali-Soluble Resin 1

Into a nitrogen-purged flask equipped with a dry ice/methanol refluxing device, 5.0 g of 2,2′-azobisisobutyronitrile as a polymerization initiator and 90 g of diethylene glycol ethyl methyl ether as a polymerization solvent were charged, and the resulting mixture was stirred. In the resulting solution, 10 g of methacrylic acid, 15 g of p-isopropenylphenol, 25 g of tricycle[5.2.1.0^{2,6}]decanyl methacrylate, 20 g of isobornyl acrylate and 30 g of n-butyl acrylate were added to start stirring, and a temperature was raised up to 80° C. Then, the resulting mixture was heated at 80° C. for 6 hours.

After completion of heating, the reaction product was added dropwise into a large amount of cyclohexane to cause coagulation. The coagulated substance was washed with water, and the coagulated substance was redissolved into tetrahydrofuran in the same mass as the mass of the coagulated substance, and then the resulting solution was added dropwise into a large amount of cyclohexane to cause coagulation again. These redissolving and coagulation works were performed three times in total, and then the resulting coagulated substance was dried in vacuum at 40° C. for 48 hours to obtain an alkali-soluble resin 1. A weight-average molecular weight of the alkali-soluble resin 1 was 10,000.

### [Synthesis Example 2] Synthesis of Alkali-Soluble Resin 2

Into a nitrogen-purged flask equipped with a dry ice/methanol refluxing device, 5.0 g of 2,2′-azobisisobutyronitrile as a polymerization initiator and 90 g of diethylene glycol ethyl methyl ether as a polymerization solvent were charged, and the resulting mixture was stirred. To the resulting solution, 10 g of methacrylic acid, 15 g of p-isopropenylphenol, 25 g of tricycle[5.2.1.0^{2.6}]decanyl methacrylate, 20 g of tricycle[5.2.1.0^{2.6}]decanyl acrylate and 30 g of n-butyl acrylate were added to start stirring, and a temperature was raised up to 80° C. Then, the resulting mixture was heated at 80° C. for 6 hours.

After completion of heating, the reaction product was added dropwise into a large amount of cyclohexane to cause coagulation. The coagulated substance was washed with water, and the coagulated substance was redissolved into tetrahydrofuran in the same mass as the mass of the coagulated substance, and then the resulting solution was added dropwise into a large amount of cyclohexane to cause coagulation again. These redissolving and coagulation works were performed three times in total, and then the resulting coagulated substance was dried in vacuum at 40° C. for 48 hours to obtain an alkali-soluble resin 2. A weight-average molecular weight of the alkali-soluble resin 2 was 10,000.

### [Preparation Example 1] Preparation of Photosensitive Resin Composition 1

Then, 100 parts of the alkali-soluble resin 1 synthesized in Synthesis Example 1, 50 parts of polyester acrylate (trade name “ARONIX M-8060”, manufactured by Toagosei Co., Ltd.), 5 parts of trimethylolpropane triacrylate, 4 parts of diphenyl(2,4,6-trimethylbenzoyl)phosphine oxide (trade name “LUCIRIN TPO”, manufactured by BASF SE), 0.4 part of a compound represented by the following formula (1), 100 parts of propylene glycol monomethyl ether acetate and 0.1 part of a fluorine-type surface active agent (trade name “Futergent FTX-218”, manufactured by NEOS COMPANY LIMITED) were mixed and stirred to obtain a homogeneous solution. This solution was subjected to filtration through a capsule filter having a pore diameter of 10 μm to prepare a photosensitive resin composition 1.

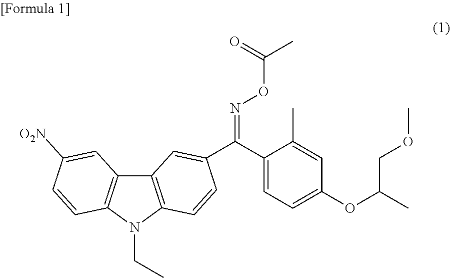 [SMILES: CCn1c2ccc(/C(=N/OC(C)=O)c3ccc(OC(C)COC)cc3C)cc2c2cc([N+](=O)[O-])ccc21]

### [Preparation Example 2] Preparation of Photosensitive Resin Composition 2

Then, 100 parts of the alkali-soluble resin 1 synthesized in Synthesis Example 1, 50 parts of polyester acrylate (trade name “ARONIX M-8060”, manufactured by Toagosei Co., Ltd.), 4 parts of diphenyl(2,4,6-trimethylbenzoyl)phosphine oxide (trade name “LUCIRIN TPO”, manufactured by BASF SE), 19 parts of 2,2-dimethoxy-1,2-diphenylethane-1-one (trade name “IRGACURE 651”, manufactured by BASF SE), 80 parts of propylene glycol monomethyl ether acetate and 0.1 part of a fluorine-type surface active agent (trade name “Futergent FTX-218”, manufactured by NEOS COMPANY LIMITED) were mixed and stirred to obtain a homogeneous solution. This solution was subjected to filtration through a capsule filter having a pore diameter of 10 μm to prepare a photosensitive resin composition 2.

### [Preparation Example 3] Preparation of Photosensitive Resin Composition 3

Then, 100 parts of the alkali-soluble resin 1 synthesized in Synthesis Example 1, 50 parts of polyester acrylate (trade name “ARONIX M-8060”, manufactured by Toagosei Co., Ltd.), 5 parts of trimethylolpropane triacrylate, 4 parts of diphenyl(2,4,6-trimethylbenzoyl)phosphine oxide (trade name “LUCIRIN TPO”, manufactured by BASF SE), 0.4 part of a compound represented by the above-described formula (1), 100 parts of propylene glycol monomethyl ether acetate, 5 parts of methacryloxypropyltrimethoxysilane and 0.1 part of a fluorine-type surface active agent (trade name “Futergent FTX-218”, manufactured by NEOS COMPANY LIMITED) were mixed and stirred to obtain a homogeneous solution. This solution was subjected to filtration through a capsule filter having a pore diameter of 10 μm to prepare a photosensitive resin composition 3.

### [Preparation Example 4] Preparation of Photosensitive Resin Composition 4

Then, 100 parts of the alkali-soluble resin 1 synthesized in Synthesis Example 1, 50 parts of polyester acrylate (trade name “ARONIX M-8060”, manufactured by Toagosei Co., Ltd.), 5 parts of trimethylolpropane triacrylate, 4 parts of diphenyl(2,4,6-trimethylbenzoyl)phosphine oxide (trade name “LUCIRIN TPO”, manufactured by BASF SE), 0.4 part of a compound represented by the above-described formula (1), 100 parts of propylene glycol monomethyl ether acetate, 5 parts of 3-glycidoxypropyltrimetoxysilane and 0.1 part of a fluorine-type surface active agent (trade name “Futergent FTX-218”, manufactured by NEOS COMPANY LIMITED) were mixed and stirred to obtain a homogeneous solution. This solution was subjected to filtration through a capsule filter having a pore diameter of 10 μm to prepare a photosensitive resin composition 4.

### [Preparation Example 5] Preparation of Photosensitive Resin Composition 5

Then, 100 parts of the alkali-soluble resin synthesized in Synthesis Example 1, 50 parts of polyester acrylate (trade name “ARONIX M-8060”, manufactured by Toagosei Co., Ltd.), 5 parts of trimethylolpropane triacrylate, 4 parts of diphenyl(2,4,6-trimethylbenzoyl)phosphine oxide (trade name “LUCIRIN TPO”, manufactured by BASF SE), 0.4 part of a compound represented by the above-described formula (1), 100 parts of propylene glycol monomethyl ether acetate, 5 parts of tris(3-(trimethoxysilyl)propyl)isocyanurate and 0.1 part of a fluorine-type surface active agent (trade name “Futergent FTX-218”, manufactured by NEOS COMPANY LIMITED) were mixed and stirred to obtain a homogeneous solution. This solution was subjected to filtration through a capsule filter having a pore diameter of 10 μm to prepare a photosensitive resin composition 5.

### [Preparation Example 6] Preparation of Photosensitive Resin Composition 6

Then, 100 parts of the alkali-soluble resin 2 synthesized in Synthesis Example 2, 50 parts of polyester acrylate (trade name “ARONIX M-8060”, manufactured by Toagosei Co., Ltd.), 5 parts of trimethylolpropane triacrylate, 1 part of 1-[9-ethyl-6-(2-methylbenzoyl)-9H-carbazole-3-yl]-ethanone 1-(O-acetyloxime), 100 parts of propylene glycol monomethyl ether acetate and 0.1 part of a fluorine-type surface active agent (trade name “Futergent FTX-218”, manufactured by NEOS COMPANY LIMITED) were mixed and stirred to obtain a homogeneous solution. This solution was subjected to filtration through a capsule filter having a pore diameter of 10 μm to prepare a photosensitive resin composition 6.

### 3. Production Process for Solder Electrode

### Example 1

Onto a substrate having plural copper electrode pads on a silicon board, the photosensitive resin composition 1 prepared in Preparation Example 1 was coated by the use of a spin coater, and the resulting material was heated on a hot plate at 120° C. for 5 minutes to form a coating film having a thickness of 55 μm. Subsequently, the resulting material was exposed to light having a wavelength of 420 nm at an irradiation intensity of 300 mJ/cm² through a pattern mask by the use of Aligner (manufactured by Suss Microtec SE, model “MA-200”). After exposure to light, the coating film was brought into contact with a 2.38 mass % tetramethylammonium hydroxide aqueous solution for 240 seconds, and the coating film was washed with running water and developed. Subsequently, the resulting material was heated in a convection oven at 200° C. for 10 minutes under flow of nitrogen to form a resist holding substrate having openings in parts corresponding to the electrode pads. When observation by an electron microscope was carried out, an open tip of each opening had a circular shape having a diameter of 30 μm, and a depth of each opening was 50 μm. Moreover, a maximum width of the opening was 30 μm.

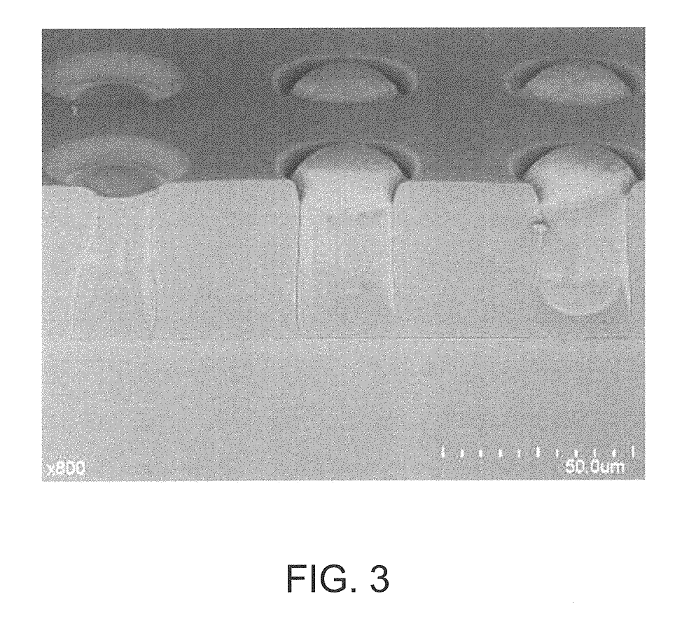

The resist holding substrate having openings was immersed into a 1 mass % sulfuric acid aqueous solution at 23° C. for one minute, and then washed with water and dried. The openings of the substrate after drying were filled with molten solder obtained by melting SAC305 (lead-free solder, trade name, manufactured by Senju Metal Industry Co., Ltd.) at 250° C. in 10 minutes while being heated to 250° C. When the resist holding substrate after being filled with the molten solder was observed by an electron microscope, it was confirmed that no cracks were found in the resist, and the openings were satisfactorily filled with the molten solder, and the solder electrode was satisfactorily formed. An electron microscope image obtained is shown in FIG. 3.

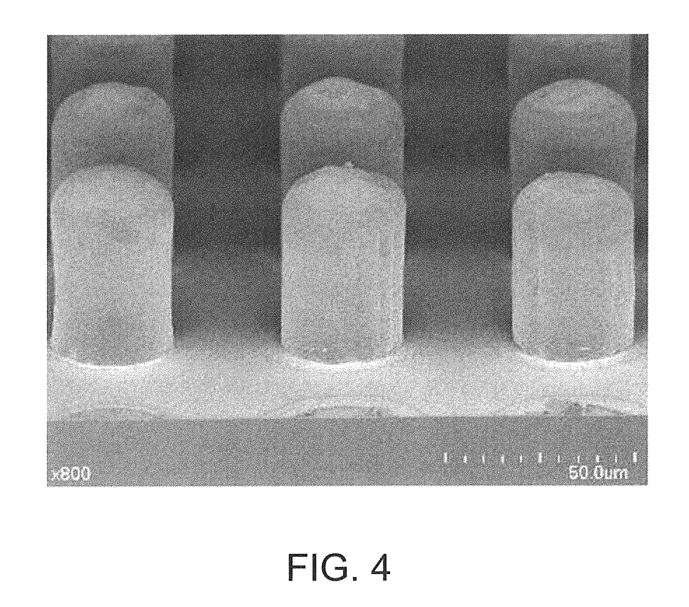

Then, the resist holding substrate on which the solder electrode was formed was immersed into a solution containing dimethyl sulfoxide/tetramethylammonium hydroxide/water at 90/3/7 (mass ratio) for 20 minutes at 50° C. to peel the resist, and the resist was washed with water and dried. An electron microscope image of the solder electrode in a state in which resist was peeled is shown in FIG. 4.

Another substrate having copper electrode pads was placed on the substrate having copper electrode pads through the solder electrode so that both may take an electrical connection structure. A pressure of 0.3 MPa was applied to two sheets of the substrates having the copper electrode pads by using a die bonder device at 250° C. for 30 seconds so that both may be fixed by applying pressure to produce a laminate consisting of the substrate having copper electrode pads, the solder electrode and the substrate having copper electrode pads in this order. Because the solder electrode was satisfactorily formed on the substrate, this laminate was able to be applied to an electronic component, such as a semiconductor device.

### Example 2

Onto a substrate having plural copper electrode pads on a silicon board, the photosensitive resin composition 2 prepared in Preparation Example 2 was coated by the use of a spin coater, and the resulting material was heated on a hot plate at 120° C. for 5 minutes to form a coating film having a thickness of 55 μm. Subsequently, the resulting material was exposed to light having a wavelength of 420 nm at an irradiation intensity of 300 mJ/cm² through a pattern mask by the use of Aligner (manufactured by Suss Microtec SE, model “MA-200”). After exposure to light, the coating film was brought into contact with a 2.38 mass % tetramethylammonium hydroxide aqueous solution for 240 seconds, and the coating film was washed with running water and developed. Subsequently, the resulting material was heated in a convection oven at 200° C. for 10 minutes under flow of nitrogen to form a resist holding substrate having openings in parts corresponding to the electrode pads. When observation by an electron microscope was carried out, an open tip of each opening had a circular shape having a diameter of 30 μm, and a depth of each opening was 50 μm. Moreover, a maximum width of the opening was 30 μm.

The resist holding substrate having openings was immersed in a 1 mass % sulfuric acid aqueous solution at 23° C. for 1 minute, and then washed with water and dried. The openings of the substrate after drying were filled with molten solder obtained by melting SAC305 (lead-free solder, trade name, manufactured by Senju Metal Industry Co., Ltd.) at 250° C. in 10 minutes while being heated to 250° C. When the resist holding substrate after being filled with the molten solder was observed by an electron microscope, it was confirmed that no cracks were found in the resist, and the openings were satisfactorily filled with the molten solder, and the solder electrode was satisfactorily formed.

### Example 3

Onto a substrate having plural copper electrode pads on a silicon board, the photosensitive resin composition 1 prepared in Preparation Example 1 was coated by the use of a spin coater, and the resulting material was heated on a hot plate at 120° C. for 5 minutes to form a coating film having a thickness of 55 μm. Subsequently, the resulting material was exposed to light having a wavelength of 420 nm at an irradiation intensity of 300 mJ/cm² through a pattern mask by the use of Aligner (manufactured by Suss Microtec SE, model “MA-200”). After exposure to light, the coating film was brought into contact with a 2.38 mass % tetramethylammonium hydroxide aqueous solution for 240 seconds, and the coating film was washed with running water and developed. Subsequently, the coating film after development was exposed to light at 1,000 mJ/cm² and then heated in a convection oven at 200° C. for 10 minutes under flow of nitrogen to form a resist holding substrate having openings in parts corresponding to the electrode pads. When observation by an electron microscope was carried out, an open tip of each opening had a circular shape having a diameter of 30 μm, and a depth of each opening was 50 μm. Moreover, a maximum width of the openings was 30 μm.

The resist holding substrate having openings was immersed in a 1 mass % sulfuric acid aqueous solution at 23° C. for 1 minute, and then washed with water and dried. The openings of the substrate after drying were filled with molten solder obtained by melting SAC305 (lead-free solder, trade name, manufactured by Senju Metal Industry Co., Ltd.) at 250° C. in 10 minutes while being heated to 250° C. When the resist holding substrate after being filled with the molten solder was observed by an electron microscope, it was confirmed that no cracks were found in the resist, and the openings were satisfactorily filled with the molten solder, and the solder electrode was satisfactorily formed.

### Example 4

A resist holding substrate having openings was produced in the same manner as in Example 2 except that the photosensitive resin composition 3 was used in place of the photosensitive resin composition 2. When observation by an electron microscope was carried out, an open tip of each opening had a circular shape having a diameter of 30 μm, and a depth of each opening was 50 μm. Moreover, a maximum width of the openings was 30 μm.

The resist holding substrate having openings was immersed in a 1 mass % sulfuric acid aqueous solution at 23° C. for 1 minute, and then washed with water and dried. The openings of the substrate after drying were filled with molten solder obtained by melting SAC305 (lead-free solder, trade name, manufactured by Senju Metal Industry Co., Ltd.) at 250° C. in 10 minutes while being heated to 250° C. When the resist holding substrate after being filled with the molten solder was observed by an electron microscope, it was confirmed that no cracks were found in the resist, and the openings were satisfactorily filled with the molten solder, and the solder electrode was satisfactorily formed.

### Example 5

A resist holding substrate having openings was produced in the same manner as in Example 2 except that the photosensitive resin composition 4 was used in place of the photosensitive resin composition 2. When observation by an electron microscope was carried out, an open tip of each opening had a circular shape having a diameter of 30 μm, and a depth of each opening was 50 μm. Moreover, a maximum width of the openings was 30 μm.

The resist holding substrate having openings was immersed into a 1 mass % sulfuric acid aqueous solution at 23° C. for 1 minute, and then washed with water and dried. The openings of the substrate after drying were filled with molten solder obtained by melting SAC305 (lead-free solder, trade name, manufactured by Senju Metal Industry Co., Ltd.) at 250° C. in 10 minutes while being heated to 250° C. When the resist holding substrate after being filled with the molten solder was observed by an electron microscope, it was confirmed that no cracks were found in the resist, and the openings were satisfactorily filled with the molten solder, and the solder electrode was satisfactorily formed.

### Example 6

A resist holding substrate having openings was produced in the same manner as in Example 2 except that the photosensitive resin composition 5 was used in place of the photosensitive resin composition 2. When observation by an electron microscope was carried out, an open tip of each opening had a circular shape having a diameter of 30 μm, and a depth of each opening was 50 μm. Moreover, a maximum width of the openings was 30 μm.

The resist holding substrate having openings was immersed into a 1 mass % sulfuric acid aqueous solution at 23° C. for 1 minute, and then washed with water and dried. The openings of the substrate after drying were filled with molten solder obtained by melting SAC305 (lead-free solder, trade name, manufactured by Senju Metal Industry Co., Ltd.) at 250° C. in 10 minutes while being heated to 250° C. When the resist holding substrate after being filled with the molten solder was observed by an electron microscope, it was confirmed that no cracks were found in the resist, and the openings were satisfactorily filled with the molten solder, and the solder electrode was satisfactorily formed.

### Example 7

Onto a substrate having plural copper electrode pads on a silicon board, the photosensitive resin composition 6 prepared in Preparation Example 6 was coated by the use of a spin coater, and the resulting material was heated on a hot plate at 120° C. for 5 minutes to form a coating film having a thickness of 55 μm. Subsequently, the resulting material was exposed to light having a wavelength of 365 nm at an irradiation intensity of 200 mJ/cm² through a pattern mask by the use of Aligner (manufactured by Suss Microtec SE, model “MA-200”). After exposure to light, the coating film was brought into contact with a 2.38 mass % tetramethylammonium hydroxide aqueous solution for 240 seconds, and the coating film was washed with running water and developed. Subsequently, the resulting material was heated in a convection oven at 200° C. for 10 minutes under flow of nitrogen to form a resist holding substrate having openings in parts corresponding to the electrode pads. When observation by an electron microscope was carried out, an open tip of each opening had a circular shape having a diameter of 30 μm, and a depth of each opening was 50 μm. Moreover, a maximum width of the openings was 30 μm.

The resist holding substrate having openings was immersed in a 1 mass % sulfuric acid aqueous solution at 23° C. for 1 minute, and then washed with water and dried. The openings of the substrate after drying were filled with molten solder obtained by melting SAC305 (lead-free solder, trade name, manufactured by Senju Metal Industry Co., Ltd.) at 250° C. in 10 minutes while being heated to 250° C. When the resist holding substrate after being filled with the molten solder was observed by an electron microscope, it was confirmed that no cracks were found in the resist, and the openings were satisfactorily filled with the molten solder, and the solder electrode was satisfactorily formed.

### Comparative Example 1

Onto a substrate having plural copper electrode pads on a silicon board, the photosensitive resin composition 2 prepared in Preparation Example 2 was coated by the use of a spin coater, and the resulting material was heated on a hot plate at 120° C. for 5 minutes to form a coating film having a thickness of 55 μm. Subsequently, the resulting material was exposed to light having a wavelength of 420 nm at an irradiation intensity of 300 mJ/cm² through a pattern mask by the use of Aligner (manufactured by Suss Microtec SE, model “MA-200”). After exposure to light, the coating film was brought into contact with a 2.38 mass % tetramethylammonium hydroxide aqueous solution for 240 seconds, the coating film was washed with running water and developed to form a resist holding substrate having openings in parts corresponding to the electrode pads. Neither heating nor exposure to light was performed after development. When observation by an electron microscope was carried out, an open tip of each opening had a circular shape having a diameter of 30 μm, and a depth of each opening was 50 μm. Moreover, a maximum width of the openings was 30 μm.

The resist holding substrate having openings was immersed into a 1 mass % sulfuric acid aqueous solution at 23° C. for 1 minute, and then washed with water and dried. The openings of the substrate after drying were filled with molten solder obtained by melting SAC305 (lead-free solder, trade name, manufactured by Senju Metal Industry Co., Ltd.) at 250° C. in 10 minutes while being heated to 250° C. When the resist holding substrate after being filled with the molten solder was observed by an electron microscope, it was confirmed that cracks were developed in the resist. Moreover, the openings were unable to be satisfactorily filled with the molten solder.

### REFERENCE SIGNS LIST

1, 11 Substrate
2, 12 Electrode pad
3 Coating film
4 Opening
5 Resist
6 Solder electrode
10, 20 Laminate

1. A production process for a solder electrode, comprising:
a step (1) of forming a coating film of a photosensitive resin composition on a substrate having an electrode pad;
a step (2) of forming resist having an opening in a region corresponding to the electrode pad by selectively exposing the coating film to light and further developing the film;
a step (3) of heating and/or exposing the resist to light; and
a step (4) of filling the opening with molten solder while heating the molten solder.

2. The production process for the solder electrode as claimed in claim 1, wherein the step (3) is a step of heating the resist.

3. The production process for the solder electrode as claimed in claim 2, wherein a heating temperature in the step (3) is 100 to 300° C.

4. The production process for the solder electrode as claimed in claim 1, further comprising a step (5) of peeling the resist from the substrate.

5. A solder electrode, produced by the production process for the solder electrode as claimed in claim 1.

6. A production process for a laminate, comprising:
a step (1) of forming a coating film of a photosensitive resin composition on a first substrate having an electrode pad;
a step (2) of forming resist having an opening in a region corresponding to the electrode pad by selectively exposing the coating film to light and further developing the film;
a step (3) of heating and/or exposing the resist to light;
a step (4) of producing a solder electrode by filling the opening with molten solder while heating the molten solder; and
a step (6) of forming an electrical connection structure between the electrode pad of the first substrate and an electrode pad of a second substrate having the electrode pad through the solder electrode.

7. A production process for a laminate, comprising:
a step (1) of forming a coating film of a photosensitive resin composition on a first substrate having an electrode pad;
a step (2) of forming resist having an opening in a region corresponding to the electrode pad by selectively exposing the coating film to light and further developing the film;
a step (3) of heating and/or exposing the resist to light;
a step (4) of producing a solder electrode by filling the opening with molten solder while heating the molten solder;
a step (5) of peeling the resist from the first substrate; and
a step (6) of forming an electrical connection structure between the electrode pad of the first substrate and an electrode pad of a second substrate having the electrode pad through the solder electrode.

8. A laminate, produced by the production process for the laminate as claimed in claim 6.

9. An electronic component, comprising the laminate as claimed in claim 8.

10. A laminate, produced by the production process for the laminate as claimed in claim 7.

11. An electronic component, comprising the laminate as claimed in claim 10.
